(19) United States
(12) Patent Application Publication
(10) Pub. No.: US 2007/0108603 A1
(43) Pub. Date: May 17, 2007

(54) Method of putting isolated metallic interconnections onto a metallic substrate

(75) Inventors: Mark Henry S. Antiporta, Manila (PH); Fernando V. Capinig, Quezon City (PH)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: PSi Technologies, Inc.

(21) Appl. No.: 11/281,197

(22) Filed: Nov. 16, 2005

(51) Int. Cl. H01L 23/48; H01L 23/52; H01L 29/40

(52) U.S. Cl. 257/734

(57) ABSTRACT

A method and substrate are provided for supporting one or more electronic devices including a first layer having a plurality of interconnected metallic frames laid out in a predetermined pattern. Each frame includes a frame member surrounding at least a portion of each frame, one or more metal pads and a plurality of metal tabs. Each tab connects to at least one of a metal pad and the frame member. A second generally planar nonconductive layer is secured to and covering at least a portion of a first surface of one or more metal pads. The nonconductive layer insulates the covered portion of the first surface of the at least one metal pad. A third generally planar layer that has a plurality of conductive traces is provided. Each trace has a first surface that is secured to and covers at least a portion of the nonconductive layer and a second surface that receives and supports an electronic device.

### BACKGROUND OF THE INVENTION

This invention relates to a substrate and a method for putting isolated conductive (e.g., metallic) interconnections on the substrate and supporting electronic devices thereon for a predefined circuit design.

The completed package of the present invention is similar to a QFN (Quad Flat No-lead) package with the addition of a nonconductive layer and a layer of conductive interconnections. The QFN package is a leadless package with terminal pads on all sides, which provide an option for mechanical and thermal enhancement. The QFN package is either square or rectangular in shape. Typically, a QFN package supports and encases semiconductor dies or chips for protection against external elements.

In producing a conventional QFN package for a semiconductor die or chip, a paddle supports the die or chip above the inner ends of a plurality of terminals. The die attaches to an upper surface of the paddle using an adhesive. Then bond wires electrically couple or interconnect the die to terminals of the package to provide external package interconnections. The QFN package is enclosed by an encapsulant, typically a moldable resin material. The resin material extends upwardly above the semiconductor die and the top of the bond wire loops. The encapsulant protects the semiconductor die or chip and the bond wires from an external surrounding environment.

In general, conventional plastic and ceramic packages incorporate several common elements. The common elements include a sealed package enclosure, a die attachment area, bond wires for providing electrical communication with bond pads on the die, and leads or terminals for external connectivity through the package.

The present invention relates to the QFN package and is directed to a substrate that includes layers for which a predefined circuit design is implemented in lieu of a complete electronic system/device. The present invention is further directed to a method of fabricating a substrate with layers that include conductive traces applied onto a nonconductive layer. One layer comprises conductive traces instead of typical bond wires, in which the traces are generally planar. The advantage of using conductive traces on top of a non-conductive layer is the ability to put an entire working system and/or circuit in at least one of a plurality of paddle. Other advantages of the conductive traces over the bond wires are that the conductive traces are shorter in length with no loops created above the layer, which makes the completed package thinner.

### BRIEF SUMMARY OF THE INVENTION

Briefly stated, a preferred embodiment of the present invention comprises a substrate for supporting one or more electronic devices. The substrate comprises a first layer that includes a plurality of interconnected metallic frames laid out in a predetermined pattern. Each frame has a frame member that surrounds at least a portion of the frame, one or more metal pads and a plurality of metal tabs. Each tab connects to at least one of the frame member and/or a metal pad. A second generally planar nonconductive layer is secured to and covers at least a portion of a first surface of one or more of the metal pads. The nonconductive layer insulates the covered portion of the first surface of at least one metal pad. A third generally planar layer comprises a plurality of conductive traces applied to at least a portion of the nonconductive layer. Each trace has a first surface secured to and covering at least a portion of the nonconductive layer and a second surface that receives and supports electronic devices.

The present invention provides a preferred method of fabricating a substrate that supports one or more electronic devices. The method includes providing a first layer that has a plurality of interconnected metallic frames arranged in a predetermined pattern. Each metallic frame includes a frame member that surrounds at least a portion of the frame, one or more metal pads, and a plurality of metal tabs. Each metal tab connects to the frame member and/or at least one or more metal pads. A second generally planar nonconductive layer is secured to and covers at least a portion of a first surface of at least one of the metal pads. The nonconductive layer insulates the covered portion of the first surface of at least one metal pad. A third generally planar layer that has a plurality of conductive traces is provided. Each trace has a first surface that is secured to and covers at least a portion of the nonconductive layer and a second surface for receiving an electronic device. The method further includes attaching the electronic device to at least one conductive trace then encasing the substrate and the supported electronic device with an encapsulant material.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a perspective view of a substrate having a plurality of interconnected metallic frames in accordance with a preferred embodiment of the present invention;

FIG. 2 is a perspective view of the substrate of FIG. 1 laid out in a matrix of 2-by-4 interconnected frames;

FIG. 3 is a top plan view of the substrate of FIG. 1 arranged in a linear format of interconnected frames;

FIG. 4 is a top plan view of the substrate of FIG. 1 arranged in a linear combination of 2-by-4 matrices;

FIG. 5 is a perspective view of the substrate of FIG. 1 identifying a single frame arranged in a matrix of 2-by-4 interconnected frames;

FIG. 6 is an enlarged perspective view of the details of a single frame of the substrate of FIG. 1;

FIG. 7 is a greatly enlarged perspective view of some of the of the metal pads, metal tabs and a portion of the frame member for a single frame of the substrate of FIG. 1;

FIG. 8 is a perspective view of a single frame showing some of the elements;

FIG. 9 is a perspective view of a completed frame supporting a plurality of electronic devices; and

FIG. 10 is an exploded perspective view of the elements (e.g., substrate, layers, devices) of a completed frame supporting a plurality of electronic devices according to an embodiment of the present invention as illustrated in FIG. 9.

### DETAILED DESCRIPTION OF THE INVENTION

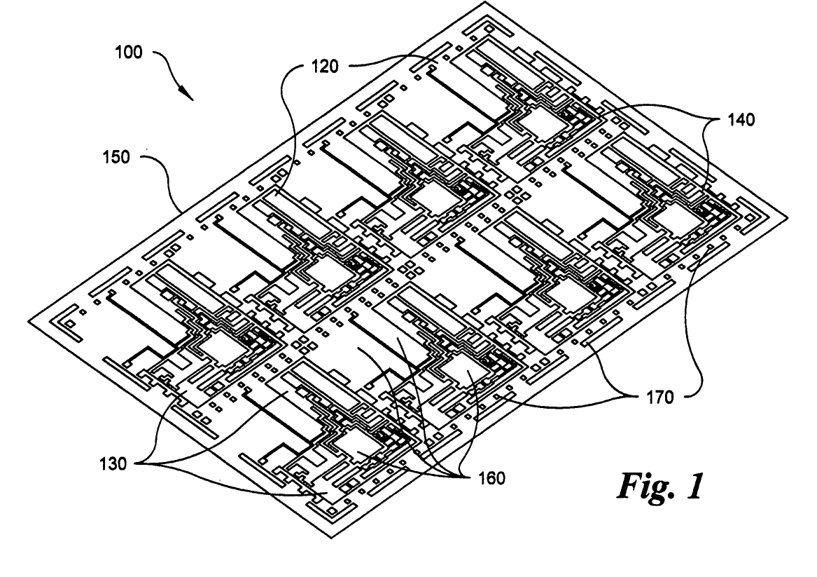

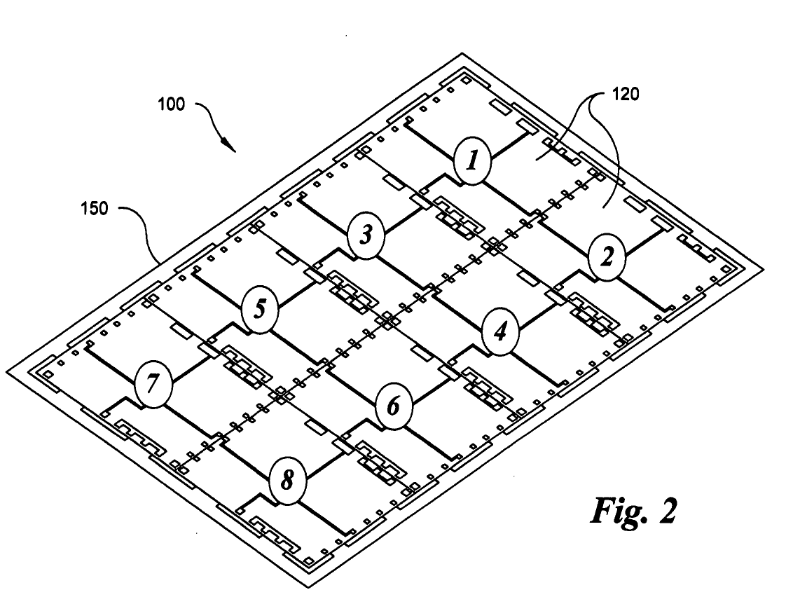

Referring to the drawings in detail, wherein like reference numerals indicate like elements throughout, there is shown in FIG. 1 a preferred embodiment of a substrate 100 in accordance with the present invention having a plurality of interconnected metallic frames 120 laid out in a predetermined pattern or format. The predetermined format as shown in FIG. 1 is laid out in a m-by-n matrix, where m is greater than one and n is greater than one. As illustrated, the matrix is 2-by-4, but it could be some other matrix. FIG. 2 shows a plurality of eight interconnected frames supported and held together by an external frame member 150.

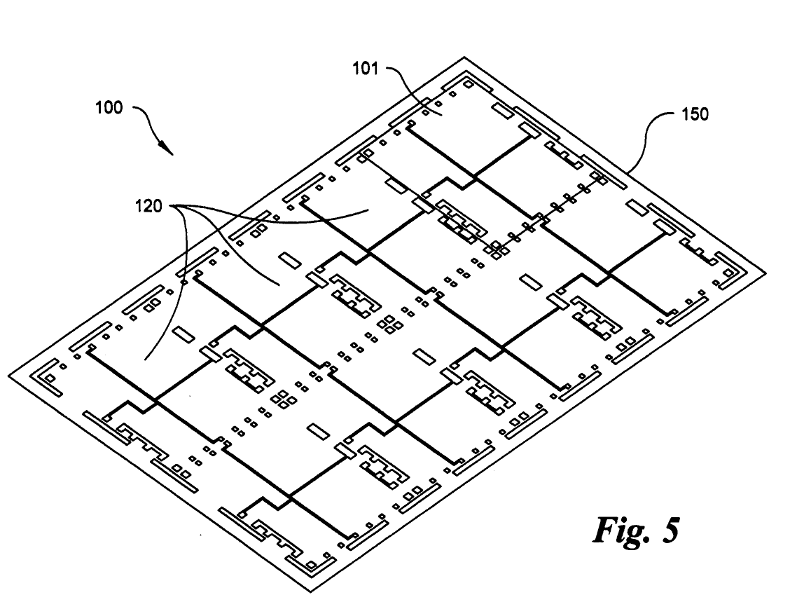

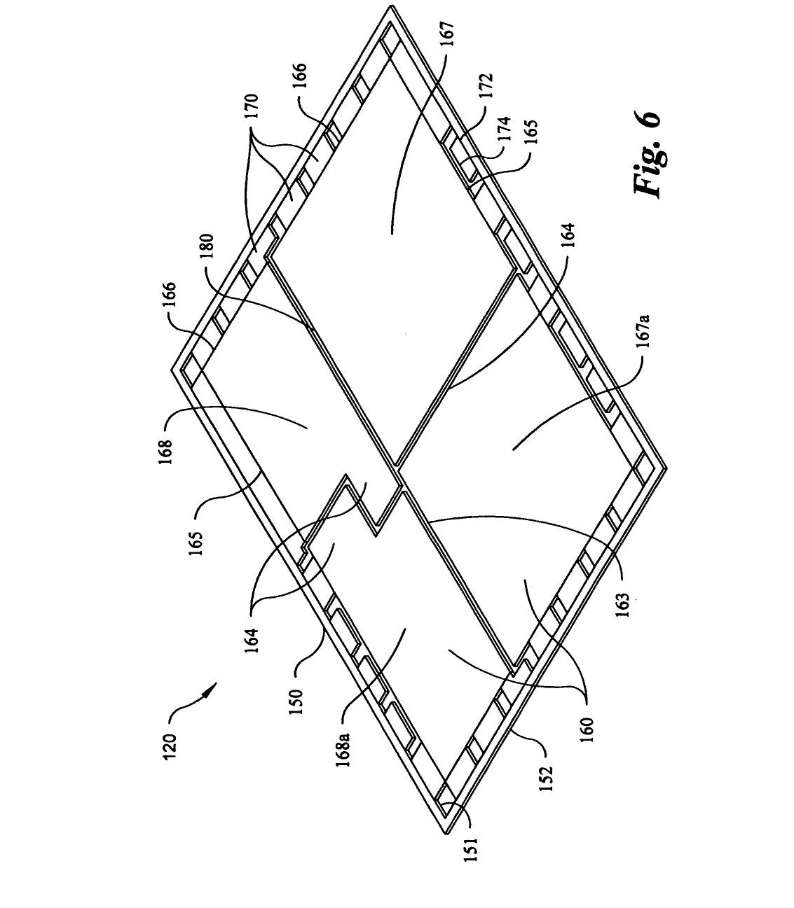

Referring to FIG. 5, there is shown an area 101 for the frame 120 in a predetermined pattern of a 2-by-4 matrix of the substrate 100, in which the frame 120 is in a first position of the 2-by-4 matrix. A detailed description for a single frame 120 according to a preferred embodiment is set forth below and as shown in FIG. 6.

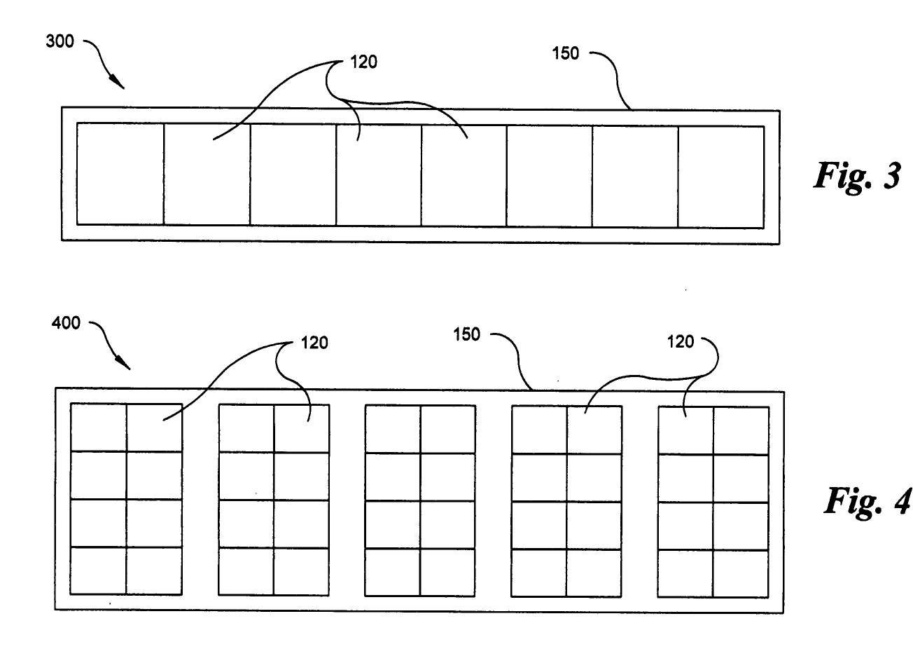

FIG. 3 shows another preferred embodiment of a substrate 300, in which a plurality of interconnected metallic frames 120 is laid out in a predetermined pattern. The predetermined pattern resembles another m-by-n matrix, where m equals 1 and n equals 8 (e.g., 1-by-8). The substrate 300 has an outer perimeter that surrounds the interconnected frames 120 and represents the frame member 150. The frame member 150 surrounds at least a portion of each interconnected frame 120 on the substrate 300. Each frame 120 on substrate 300 is a preferred embodiment of the present invention and is described in detailed as shown in FIG. 6. The predetermined pattern of frames on a substrate is laid out and resembles an m-by-n matrix that m and n can have any value, in which the matrix creates other predetermined patterns of interconnected metallic frames 120 according to additional embodiments of the present invention.

In yet another preferred embodiment, a plurality of interconnected frames 120 is laid out in another predetermined pattern as shown in FIG. 4 on a substrate 400. The predetermined pattern resembles a linear combination of m-by-n matrices, where n and m are both greater than one. For example, FIG. 4 shows a substrate 400 that has five individual groups of interconnected metallic frames 120 that are laid out in a linear combination of five 2-by-4 matrices. Each 2-by-4 matrix is separated from an adjacent matrix by the frame member 150 that surrounds at least a portion of each frame 120 for each group. The substrate 400 is one example of a preferred embodiment, it is not limiting in any way to other embodiments and therefore, the substrate can have other group arrangements or patterns of interconnected frames 120 with fewer or more groups. For example, substrate 400 can have more or less than five groups of matrices and the frames 120 in each matrix group, can be laid out in other predetermined patterns of m-by-n matrices. In addition, the predetermined pattern for each group need not be the same on the substrate. For example, a substrate can have three groups of matrices of interconnected frames 120, with a first group as a 2-by-4 matrix, a second group as a 2-by-3 matrix and the third group as a 2-by-2 matrix. One skilled in the art would recognize that a substrate could have any number of groups and each group has a form of a m-by-n matrix.

Referring now to FIG. 6, this is a preferred embodiment of the single frame 120 and the following describes the details of the frame 120. The frame 120 has four metal pads 167, 167a, 168 and 168a, twenty-eight metal tabs 170, and one frame member 150. Frame 120 is an exemplary embodiment for all substrate embodiments of the present invention. Two of the metal pads 167, 167a generally have a uniform shape including four peripheral sides 163, 164, 165, 166. Two of the peripheral sides 163, 164 are internal and adjacent to an open space 180 and the other two peripheral sides 165, 166 are external and connected to some of the metal tabs 170. The other two metal pads 168, 168a have a generally rectangular shape including four peripheral sides. Three of the peripheral sides 163, 165, 166 are generally straight and parallel to at least one internal edge 151 of the frame member 150. The fourth peripheral side 164 has a step-like shape that partially extends into an adjacent metal pad 168 or 168a without connecting the metal pads 168, 168a together. The step-like sides 164 of the metal pads 168 and 168a are separated by the open space 180 and are electrically isolated from the other metal pads 167, 167a. Each external peripheral side 165, 166 of the metal pads 167, 167a, 168, 168a connects to at least one metal tab 170, in which the metal tab 170 connects to the internal edge 151 of the frame member 150.

The metal pads 167, 167a, 168, 168a can have any shape, size and number of peripheral sides, in which the shape does not have to be uniform, which all are selected according to a predefined design. In addition, the metal pads 167, 167a, 168, 168a are made of copper, but could be made of other conductive materials such as copper alloy, nickel and nickel alloys. The metal pads 167, 167a, 168, 168a are used to support and interconnect one or more electronic devices (not shown) according to a predetermined circuit design.

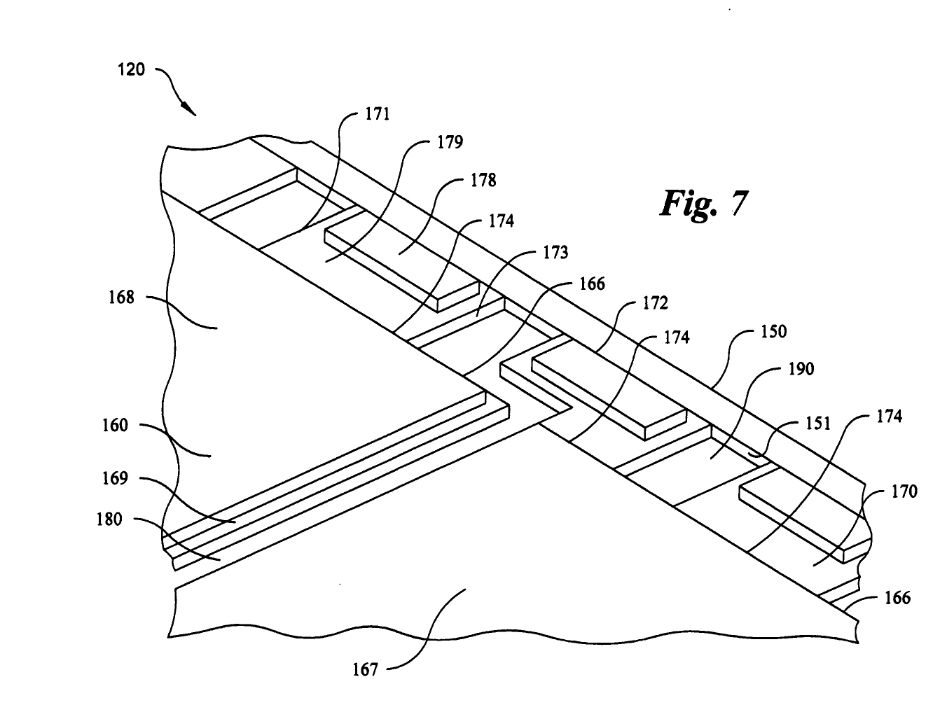

Referring to FIG. 7, the twenty-eight metal tabs 170 are generally rectangular and have four peripheral sides or ends 171, 172, 173, 174. Two of the peripheral sides or ends 171, 173 are generally short and are perpendicular to the internal edge 151 of the frame member 150, in which side 171 is opposite of side 173. The short peripheral sides or ends 171, 173 of the metal tabs 170 do not connect to anything and are exposed to an open space 190 between adjacent metal tabs 170. The open space 190 connects to the open space 180 at least once on each side of the frame 120. The open space 190 is positioned between the peripheral sides 165 and 166 of the metal pads 167 and 168 and the internal edge 151 of the frame member 150. The other two peripheral ends 172, 174 are generally long with one end 172 connecting to the internal edge 151 of the frame member 150. The opposite end 174 of metal tabs 170 may or may not be connected to the metal pads 167, 168, which is based on a predefined design. The opposite end 174 can also have a step-like shape end portion, in which the step-like end 174 partially connects to the metal pads 167, 168 with the remaining portion remaining unconnected. Referring again to FIG. 6, some metal tabs 170 have one end 172 connected to the frame member 150 and the opposite end 174 remains unconnected. Generally, all metal tabs 170 vary in length, but all can have the same length according to a predefined design or embodiment. All metal tabs 170 connect to the frame member 150 using the internal edge 151 while some metal tabs connect to the metal pads 167 and 168.

The metal tabs 170 are made of copper, but could be made of other conductive materials such as copper alloys, nickel and nickel alloys. The metal tabs 170 are used to connect and support the metal pads 167 and 168 to the frame member 150. In addition, the metal tabs 170 are used as dambars (not shown) when an encapsulant material (not shown) is used to encase the frame 120, in which the encapsulant material securely holds the metal tabs 170. When severed from the frame member 150, at least one metal tab 170 is used to provide an electrical pathway (not shown) from an electronic device through an interconnect medium (e.g. wires, clips) to an external circuit (not shown).

Referring again to FIG. 6, the frame member 150 of the frame 120 has a uniform shape and defines an outer perimeter of the frame 120. The outer perimeter forms a frame-like shape, having two sets of two perpendicular peripheral sides and can be either square or rectangular. All peripheral sides of the frame member, have an internal edge 151 and an external edge 152. The internal edge 151 connects to all metal tabs 170 and the external edge 152 connects to adjacent frames 120 on the substrate.

The frame member 150 is made of copper, but could be made of other conductive materials such as copper alloys, nickel and nickel alloys. The frame member 150 functions to support the metal pads 167, 168 that are connected to the metal tabs 170 and interconnects the plurality of interconnected frames 120. The frame 120 that is laid out in a predetermined pattern interconnects with an adjacent frame 120 by the external edge 152 of frame member 150, which isolates the frame 120 from other interconnected frames 120.

FIG. 7 is a greatly enlarged view of an area on the frame 120 showing the details of the metal pads 167, 168, the metal tabs 170, the frame member 150 and their interconnections. The details show that at least one of the sides 171, 172, 173 and 174 of the metal tab 170 has a lower step-like surface (e.g., a first surface) 179 and a second surface 178 above the first surface. At least one of the sides 163, 164, 165 and 166 of the metal pads 167 and 168 has a lower step-like surface (e.g., a first surface) 169 and a second surface 160 above the first surface. The peripheral side 172 of the metal tabs 170 connects to the internal edge 151 of the frame member 150, in which the first surface 179 is coplanar or substantially coplanar with the first surface 169 of at least one of the metal pads 167, 168. The peripheral sides 165, 166 of the metal pads 167, 168 connect to the peripheral side 174 of some metal tabs 170, in which the first surface 169 is coplanar or substantially coplanar with the first surface 179. The second surface 178 of the metal tabs 170 is coplanar or substantially coplanar with the second surface 160 of one or more metal pads 167, 168.

For another preferred embodiment (not shown), at least one first surface 179 of the metal tab 170 is not coplanar with a lower step-like surface (e.g., a first surface) 169 of the metal pads 167, 168. The second surface 178 of the metal tabs 170 is not coplanar with the second surface 160 of the metal pads 167, 168. The step-like surfaces 169 and 179 provide the encapsulant material (not shown) a place to securely hold the metal pads 167, 167a, 168 and 168a and the metal tabs 170 when encasing the frame 120 in a completed electronic package (not shown).

The frame member 150 is generally coplanar with the first surface 179 of the metal tabs 170 and the first surface 169 of the metal pads 167, 168. However, the frame member 150 is not coplanar with the second surfaces 160, 178 of the metal pads 167, 168 and the metal tabs 170. In another embodiment (not shown), frame member 150 is co-planar with the second surface 160, 178 of metal pads 167, 168 and metal tabs 170. The internal edge 151 of the frame member 150 connects to the peripheral side or end 172 of all metal tabs 170 that are adjacent to the first surface 179. An upper portion of the peripheral side 172 that is adjacent to the second surface 178 does not connect to the internal edge 151 of the frame member 150. The peripheral side 174 that is adjacent to the step-like surface 179 of some metal tabs 170 connects to the peripheral sides 165 and 166, which are adjacent to the first surface 169 of metal pads 167, 168. The peripheral side 174 does not connect to the peripheral sides 165, 166 of the metal pads 167, 168.

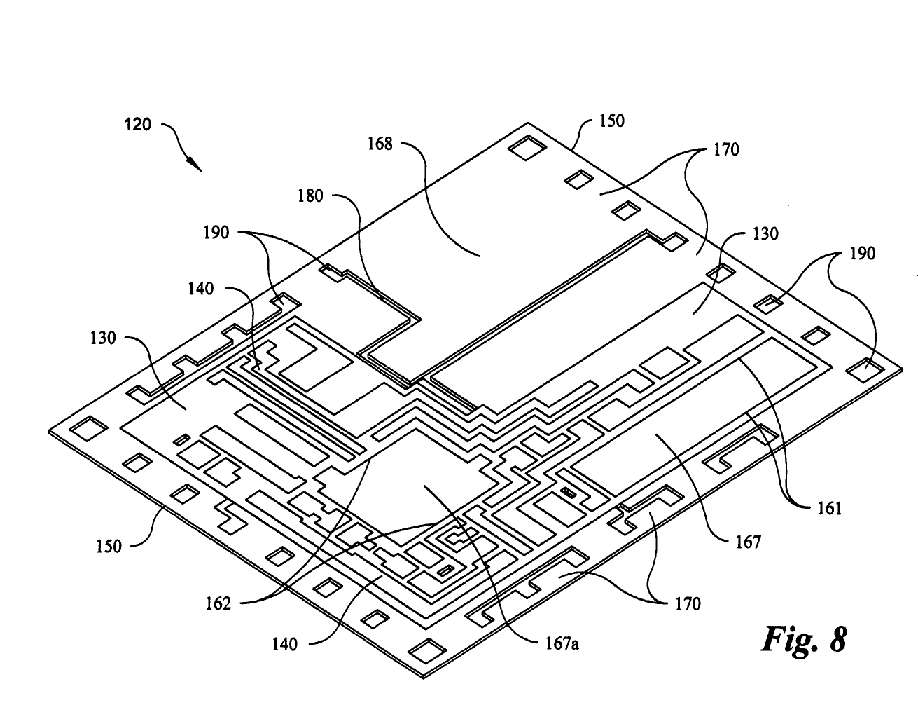

Referring now to FIG. 8, the frame 120 is shown with the second nonconductive layer 130 and the third layer having a plurality of conductive traces 140 applied. According to a preferred embodiment, the nonconductive layer 130 is made with a polyimide film, such as Kapton® tape, but could be made of other nonconductive materials with a high thermal capability.

The Kapton® tape 130 has two main surfaces, a first or top main surface and a second or bottom main surface with one or both surfaces having an adhesive pre-applied. For this embodiment, the pre-applied adhesive is used to secure the Kapton® tape 130 to and cover at least a portion of the first surface of three metal pads 167, 167a, 168, 168a and insulate the covered portions. For another embodiment, a separate adhesive may be used to secure the nonconductive layer 130 (e.g., Kapton® tape or other nonconductive material) to the metal pads 167, 167a, 168, 168a instead of having the adhesive pre-applied.

Before the Kapton® tape 130 is applied to the frame 120 or the metal pads 167, 167a, 168, 168a, it is formed by die cutting or some other forming method, to a specific shape and size according to a predefined design. One skilled in the art would recognize that other materials and other methods could be used for forming the nonconductive layer 130 before applying it to the frame 120 or to the metal pads 167, 167, 168, 168a or that it could be applied in some other manner such as spraying on.

Referring again to FIG. 8, the Kapton® tape layer 130 applied to the metal pads, 167, 167a, 168 and 168a has a specific shape and size, in which it covers a portion of the metal pads 167, 167a, 168 and 168a. The Kapton® tape 130 also covers a portion of the open space 180 by forming a bridge over the open space 180. There exist at least two open voids 161 and 162 that are formed in the Kapton® tape 130 thus allowing portions of the metal pads 167 and 167a to remain uncovered and un-insulated. The open voids 161 and 162 allow electronic devices (not shown) to be connected directly to the metal pads 167, 167a, which provide electrical interconnections between the electronic devices (not shown) and the metal pads 167 and 167a.

The conductive traces 140 of the third layer are applied to the top or first main surface of the Kapton® tape 130. The conductive traces 140 are made with copper, but could be made with other conductive materials.

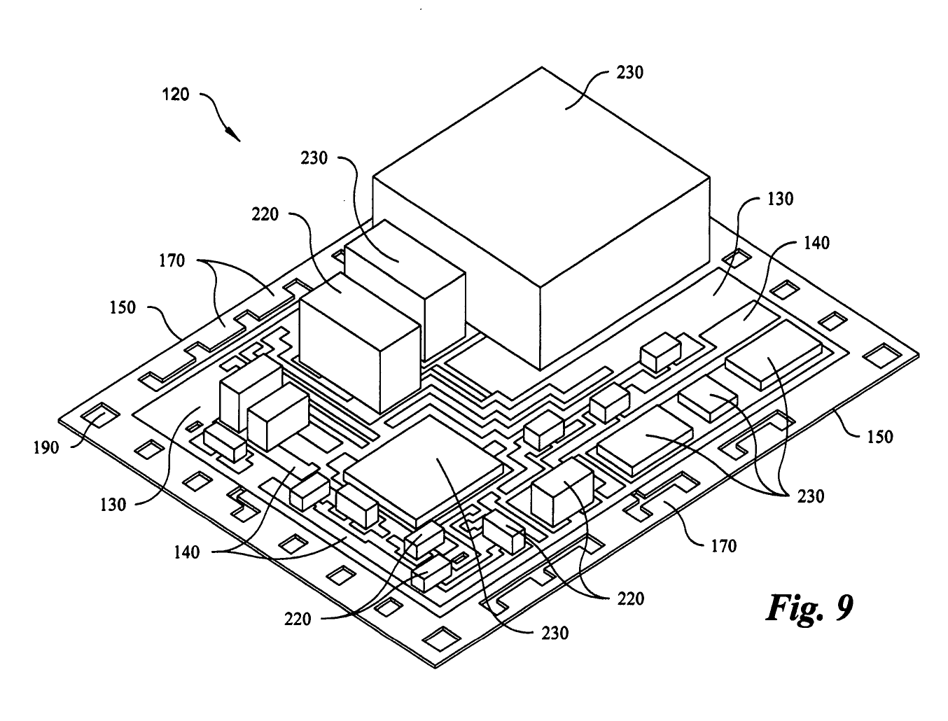

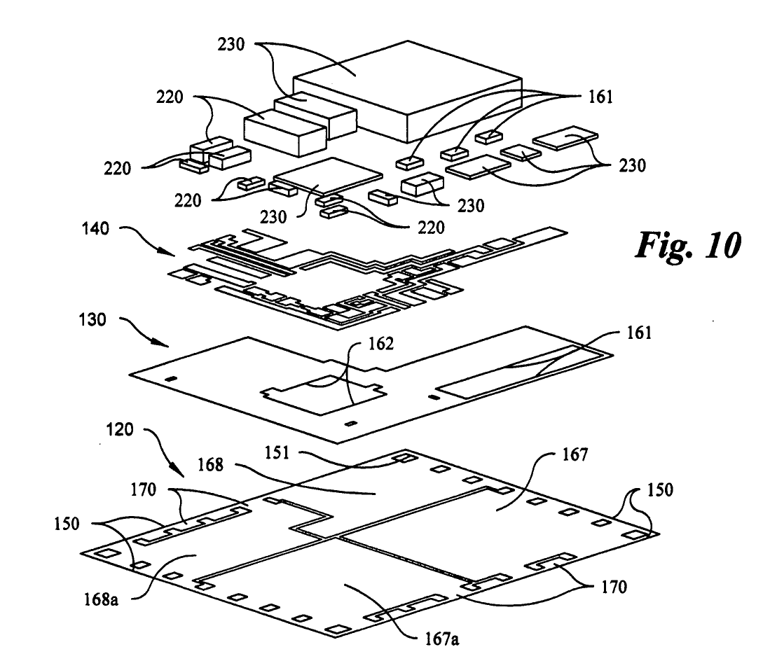

The conductive traces 140 are generally planar and have a first surface that is secured to and covers at least a portion of the top surface of the Kapton® tape 130. The conductive traces 140 have a second surface for receiving, supporting and interconnecting electronic devices as shown in FIG. 9. However, the size, shape and length of the conductive traces 140 may or may not be unique and are defined according to a predefined circuit design. Referring again to the embodiment shown in FIG. 8, the frame 120 has conductive traces 140 that have sizes, shapes and lengths for supporting electronic devices (not shown) that are attached thereon according to a predefined circuit design. Portions of some conductive traces 140 are generally straight, rectangular or square, while others are irregularly shaped with multiple bends and have varying lengths. Other conductive traces 140 are generally straight, but still have different sizes, shapes and lengths.

Before applying and securing the conductive traces 140 to the Kapton® tape 130, the Kapton® tape 130 is first prepared to receive the conductive traces 140. To prepare the top surface of the Kapton® tape, an adhesive, an epoxy or an etching material is applied for securing and forming the conductive traces 140. In a preferred embodiment, the conductive traces 140 are applied to the Kapton® tape 130 by using typical etching methods. In other preferred embodiments, the conductive traces 140 are formed by using an epoxy or Kapton® tape with an adhesive pre-applied to the top main surface, and then attaching the conductive traces 140 to the epoxy or adhesive. Once the conductive traces 140 are applied to the Kapton® tape 130, the traces 140 are ready to receive and support the electronic devices (not shown). In another preferred embodiment, the third layer 140 has two or more generally planar layers of conductive traces, thereby forming multilayer circuits (not shown). The multilayer circuits electrically connect via a node extending through the Kapton® tape (e.g., a nonconductive layer) according to a predefined design.

In a preferred embodiment of the present invention, FIG. 9 is a perspective view of a frame 120 supporting electronic devices 220 and 230, with the electronic devices 220 on the conductive traces 140 and electronic devices 230 connected directly on to the metal pads 167, 167a, 168 and 168a. The electronic devices or components 220 are applied to the conductive traces 140 and the metal pads 167, 167a, 168 or 168a using direct soldering or soldering reflowing methods. One skilled in the art would recognize that other methods may be used to attach the electronic components 220, 230 to the conductive traces 140 and the metal pads 167, 167a, 168 and 168a. The techniques listed here are exemplary methods that are used for the preferred embodiments and do not impose any limitations for using other methods. The electronic components 220, 230 are applied to the conductive traces 140 and metal pads 167, 167a, 168, 168a according to a predefined circuit design. According to a preferred embodiment, the electronic devices 220, 230 are electrically connected to at least one conductive trace 140 each and/or at least one metal pad 167, 167a, 168, 168a. At least two electronic devices 220 use the plurality of conductive traces 140 as interconnections for a predetermined circuit design.

FIG. 10 is an exploded view showing details for the frame 120 shown in FIG. 9. FIG. 10 illustrates an order for the elements that form the completed frame 120 and how the elements are positioned on the frame.

FIG. 10 shows the frame 120 surrounded by the frame member 150 that includes the plurality of metal tabs 170 and four metal pads 167, 167a, 168, 168a. All metal tabs connect to the internal edge 151 of the frame member 150 while some connect to the metal pads 167, 167, 168, 168a. Above the frame is the nonconductive layer 130 (e.g., Kapton® tape). The Kapton® tape is formed before it is applied to the metal pads 167, 167a, 168, 168a and has at least two open voids 161, 162 according to a predefined design. When applied, the nonconductive layer 130 is secured to portions of the first surface 169 of some of the metal pads 167, 167a, 168, 168a. In addition, the nonconductive layer 130 also insulates the portions that cover the metal pads 167, 167a, 168, 168a. The open voids 161, 162 allow portions of the metal tabs 167, 167a, 168, 168a to remain uncovered and un-insulated for receiving and securing electronic devices 230 directly. Above the second layer is the third layer that has a plurality of conductive traces 140. The conductive traces 140 are formed onto the Kapton® tape 130 layer. Each trace covers at least a portion of the Kapton® tape in preparation for receiving, supporting and interconnecting an electronic device 220. Above the second layer, the electronic devices 220, 230 are applied and attached to the conductive traces 140 and the metal pads 167, 167a, 168, 168a. By connecting the electronic device 230 directly to the metal pad 167, 167a, 168 or 168a, the interconnection provides electrical conductivity between the electronic device and the metal pad 167, 167a, 168, 168a. In addition, the metal pads 167, 167a, 168, 168a also provide thermal conductivity by heat sinking the temperature away from the electronic device 220, 230 according to a preferred embodiment. Afterwards, the substrate with at least one electronic device is encased with an encapsulant material for forming a completed package.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A substrate for supporting one or more electronic devices, the substrate comprising:
a first layer including a plurality of interconnected metallic frames laid out in a predetermined pattern, each frame comprising;
(i) a frame member surrounding at least a portion of each frame,
(ii) one or more metal pads, and
(iii) a plurality of metal tabs, each tab being connected to at least one of a metal pad and the frame member;
a second generally planar nonconductive layer secured to and covering at least a portion of a first surface of at least one of the metal pads for insulating the covered portion of the first surface of the at least one metal pad; and
a third generally planar layer comprising a plurality of conductive traces, each trace having a first surface secured to and covering at least a portion of the nonconductive layer and a second surface for receiving and supporting an electronic device.

2. The substrate of claim 1 wherein the metal pads support one or more electronic devices.

3. The substrate of claim 2 wherein each electronic device is electrically connected to at least one of the conductive traces, at least one of the metal pads and/or at least one of the metal tabs.

4. The substrate of claim 2 wherein the plurality of conductive traces is used to interconnect at least two electronic devices.

5. The substrate of claim 1 further comprising an encapsulant material encasing the frame and the supported electronic device.

6. The substrate of claim 5 wherein the encapsulant material securely holds the plurality of metal tabs and the one or more metal pads in a completed electronic package.

7. The substrate of claim 5 wherein at least one of the plurality of metal tabs provides interconnectivity to an external circuit.

8. The substrate of claim 1 wherein each of the of conductive traces comprises two or more generally planar layers.

9. The substrate of claim 8 wherein the plurality of generally planar layers of the plurality of conductive traces form overlapping multi-layer circuits that are electrically connected via a node extending through the nonconductive layer and electrically isolated from each layer of conductive traces by non-conductive layers interposed between each layer of conductive traces.

10. The substrate of claim 1 wherein the predetermined pattern of interconnected metallic frames comprises an m-by-n matrix, wherein m is greater than one and n is greater than one.

11. The substrate of claim 1 wherein the predetermined pattern of interconnected metallic frames comprises a linear combination of independent m-by-n matrices.

12. The substrate of claim 1 wherein each frame of the plurality of interconnected metallic frames is electrically isolated from adjacent frames.

13. The substrate of claim 1, wherein a first surface of at least one of the metal tabs is coplanar or substantially coplanar with the first surface of the metal pads.

14. The substrate of claim 1, wherein a first surface of the metal tabs is not coplanar with the first surface of the metal pads.

15. The substrate of claim 1, wherein a second surface of at least one of the metal tabs is coplanar or substantially coplanar with a second surface of the metal pads.

16. The substrate of claim 1, wherein a second surface of the metal tabs is not coplanar with a second surface of the metal pads.

17. The substrate of claim 1, wherein the metal tabs each include first and second opposite ends with one end of each tab being attached to a metal pad.

18. The substrate of claim 1, wherein the metal tabs each include first and second opposite ends with one end of each tab not being attached to a metal pad.

19. A method of fabricating a substrate to support one or more electronic devices, the method comprising:
(a) providing a first layer including a plurality of interconnected metallic frames laid out in a predetermined pattern, each metallic frame including a frame member surrounding at least a portion of each frame, one or more metal pads, and a plurality of metal tabs, each tab being connected to at least one of a metal pad and the frame member;
(b) providing a second generally planar nonconductive layer secured to and covering at least a portion of a first surface of at least one of the metal pads for insulating the covered portion of the first surface of the at least one metal pad; and
(c) providing a third generally planar layer comprising a plurality of conductive traces, each trace having a first surface secured to and covering at least a portion of the nonconductive layer and a second surface for receiving an electronic device;

20. The method of claim 19 further comprising:
(d) attaching the electronic device to at least one of the conductive traces; and
(e) encasing the substrate and electronic device with an encapsulant material.

21. The method of claim 20 further comprising:
(f) attaching the electronic device on at least one of the metal pads.

22. The method of claim 20 further comprising:
(f) attaching the electronic device on at least one of the metallic traces.

23. The method of claim 19 further comprising:
(d) forming dambars on the metallic frame utilizing the metallic tabs.

24. The method of claim 20 further comprising:
(f) severing the metal tabs to provide input/output terminals through the encapsulant material.

25. The method of claim 19 further comprising:
(d) forming an electrically conductive external interconnection utilizing at least one of the metal pads.

26. The method of claim 19 wherein the nonconductive layer is formed by using a tape of polyimide film.
